(19) United States
(12) Patent Application Publication
(10) Pub. No.: US 2011/0232725 A1
(43) Pub. Date: Sep. 29, 2011

(54) PACKAGE STRUCTURE OF CONCENTRATED PHOTOVOLTAIC CELL

(76) Inventor: Sheng-Chih Wan, Qionglin Township (TW)

(21) Appl. No.: 12/873,634

(22) Filed: Sep. 1, 2010

(30) Foreign Application Priority Data
Mar. 26, 2010 (TW) 99205336

(51) Int. Cl. H01L 31/0203

(52) U.S. Cl. 136/251

(57) ABSTRACT

A package structure of a concentrated photovoltaic cell is provided, wherein a bottom contact of a photovoltaic chip is electrically connected to a metal substrate. The metal substrate not only becomes an external electrode, but also conducts the heat generated by the photovoltaic chip away, providing the function of heat dissipation.

### BACKGROUND OF THE INVENTION

1. Field of the Invention

The present invention is related to a semiconductor package structure, and more particularly to a package structure of a concentrated photovoltaic cell.

2. Description of the Prior Art

As the oil price has remained high in recent years, much effort has been devoted to researching and developing new energy sources. Among them, solar energy has the advantage of being inexhaustible in supply and constantly available for use, and the advantage of being a clean, noise free, and pollution free natural resource. It is therefore being considered as one of the replacement energy sources with the highest potential in the future. Because the operating temperature of a concentrated photovoltaic cell module is very high, if the photovoltaic cell module is not accompanied by an effective heat dissipation mechanism, the life of photovoltaic chip may be substantially decreased, or the photovoltaic chip may even risk to be burned.

### SUMMARY OF THE INVENTION

The present invention is directed to a package structure of a concentrated photovoltaic cell, wherein the bottom contact of the photovoltaic chip is electrically connected to the metal substrate. The metal substrate not only becomes an external electrode, but also conducts the heat generated by the photovoltaic chip away, providing the function of heat dissipation.

In order to achieve the aforementioned objective, the package structure of the concentrated photovoltaic cell according to an embodiment includes a metal substrate, an insulating material, a photovoltaic chip, a circuit wiring layer and a package resin highly pervious to light. The insulating material is disposed on the metal substrate and has a first opening and a second opening exposing the metal substrate. The photovoltaic chip has at least one top contact and a bottom contact respectively on the upper surface and the lower surface of the photovoltaic chip; wherein the photovoltaic chip is disposed in the first opening of the insulating material, and the bottom contact of the photovoltaic chip is electrically connected to the metal substrate. The circuit wiring layer is disposed on the insulating material, and exposes at least one wiring contact electrically connected to the top contact of the photovoltaic chip through at least one wire, wherein the metal substrate exposed from the second opening and the wiring contact of the circuit wiring layer respectively become external electrodes for connecting electrically externally. The package resin highly pervious to light encapsulates the photovoltaic chip and part of the circuit wiring layer.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1a is a schematic diagram illustrating a package structure of the concentrated photovoltaic cell according to the embodiment of the present invention;

FIG. 1b is an A-A′ cross-sectional diagram of the package structure of the concentrated photovoltaic cell according to the embodiment of the present invention illustrated in FIG. 1a;

FIG. 2 is a schematic diagram illustrating the package structure of the concentrated photovoltaic cell according to another embodiment of the present invention;

FIG. 3a is the schematic diagram illustrating the package structure of a concentrated photovoltaic cell according to another embodiment of the present invention;

FIG. 3b is an A-A′ cross-sectional diagram illustrating the package structure of the concentrated photovoltaic cell according the embodiment of the present invention shown in FIG. 3a;

FIG. 3c is a B-B′ cross-sectional diagram illustrating the package structure of the concentrated photovoltaic cell according to the embodiment of the present invention shown in FIG. 3a; and

FIG. 4 is a schematic diagram illustrating the package structure of the concentrated photovoltaic cell according to another embodiment of the present invention.

### DESCRIPTION OF THE PREFERRED EMBODIMENT

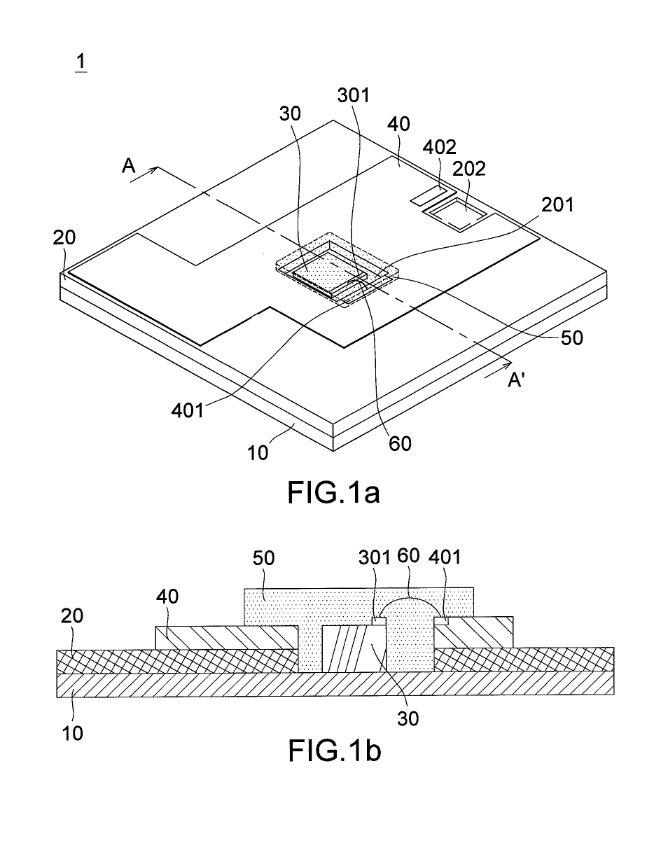

Referring to FIG. 1a, and FIG. 1b, FIG. 1a is a schematic diagram illustrating the package structure of the concentrated photovoltaic cell 1 according to an embodiment; FIG. 1b is an A-A′ cross-sectional diagram of the package structure of the concentrated photovoltaic cell 1 according to the embodiment illustrated in FIG. 1a. The package structure of the concentrated photovoltaic cell 1 includes a metal substrate 10, an insulating material 20, a photovoltaic chip 30, a circuit wiring layer 40, and a package resin highly pervious to light 50. The insulating material 20 is disposed on the metal substrate 10 and has a first opening 201 and a second opening 202 exposing the metal substrate 10. The photovoltaic chip 30, including a gallium arsenide (GaAs) photovoltaic chip, an indium phosphide (InP) photovoltaic chip, or an indium gallium phosphide (InGaP) photovoltaic chip, has at least one top contact 301 and a lower contact (not shown) respectively on the upper surface and the lower surface of the photovoltaic chip 30, wherein the photovoltaic chip 30 is disposed in the first opening 201 of the insulating material 20, and the bottom contact of the photovoltaic chip 30 is electrically connected to the metal substrate 10. The circuit wiring layer 40 is disposed on the insulating material 20, and exposes at least one wiring contact 401 then electrically connected to the top contact 301 of the photovoltaic chip 30 through at least one wire 60, wherein the metal substrate 10 exposed from the second opening 202 and the wiring contact 401 of the circuit wiring layer 40 respectively become external electrodes for connecting electrically externally. Preferably, the circuit wiring layer 40 further includes another wiring contact 402 disposed in an appropriate location in the vicinity of the second opening 202. Such arrangement facilitates the wiring contact 402 and the metal substrate 10 in the second opening 10 to respectively become electrodes for connecting electrically externally. The package resin highly pervious to light 50 encapsulates the photovoltaic chip 30 and part of the circuit wiring layer 40.

It has to be clarified that the circuit wiring layer 40 includes a conductive wiring layer and a protecting layer. The protecting layer is disposed on the conductive wiring layer, and exposes the wiring contacts 401, 402 of the conductive wiring layer. Besides, the metal substrate 10 includes material such as copper or aluminum that has higher thermal conductivity. Therefore, in the package structure of the concentrated photovoltaic cell according to the present embodiment, the bottom contact (not shown) of the photovoltaic chip 30 is electrically connected to the metal substrate 10. The metal substrate 10 not only becomes an external electrode, but also conducts the heat generated by the photovoltaic chip 30 away, providing the function of heat dissipation.

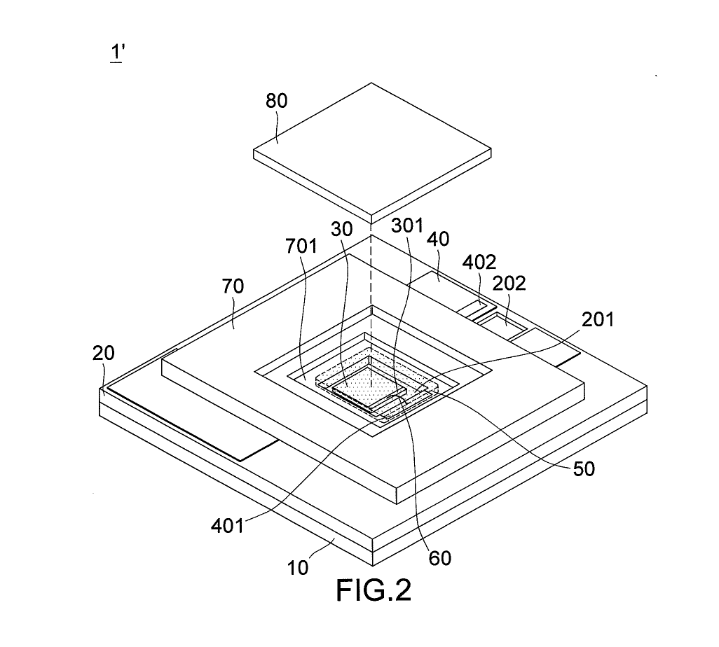

FIG. 2 is a schematic diagram illustrating the package structure of the concentrated photovoltaic cell 1′ according to another embodiment. The package structure of the concentrated photovoltaic cell 1′ further includes a protecting element 70 and a light-pervious plate 80. The protecting element 70 is disposed on the circuit wiring layer 40, and includes an opening 701 exposing the photovoltaic chip 30. Preferably, the opening 701 also exposes the wiring contact 401 of the circuit wiring layer 40, but the present invention is not limited to be implemented as such. The light-pervious plate 80 is disposed on the protecting element 70, wherein the photovoltaic chip 30 is located within the range of the light-pervious plate 80. For example, the protecting element 70 is a staircase structure enclosing the opening 701 to form an accommodating space for the light-pervious plate 80, as shown in FIG. 2, but the protecting element 70 is not limited to be implemented as such staircase structure. The addition of the protecting element 70 and the light-pervious plate 80 may block the pollutants such as the external dust and cotton fiber, ensuring the photovoltaic chip 30 to operate normally. The material of the light-pervious plate 80 includes acrylate, tempered glass, glass or polycarbonate.

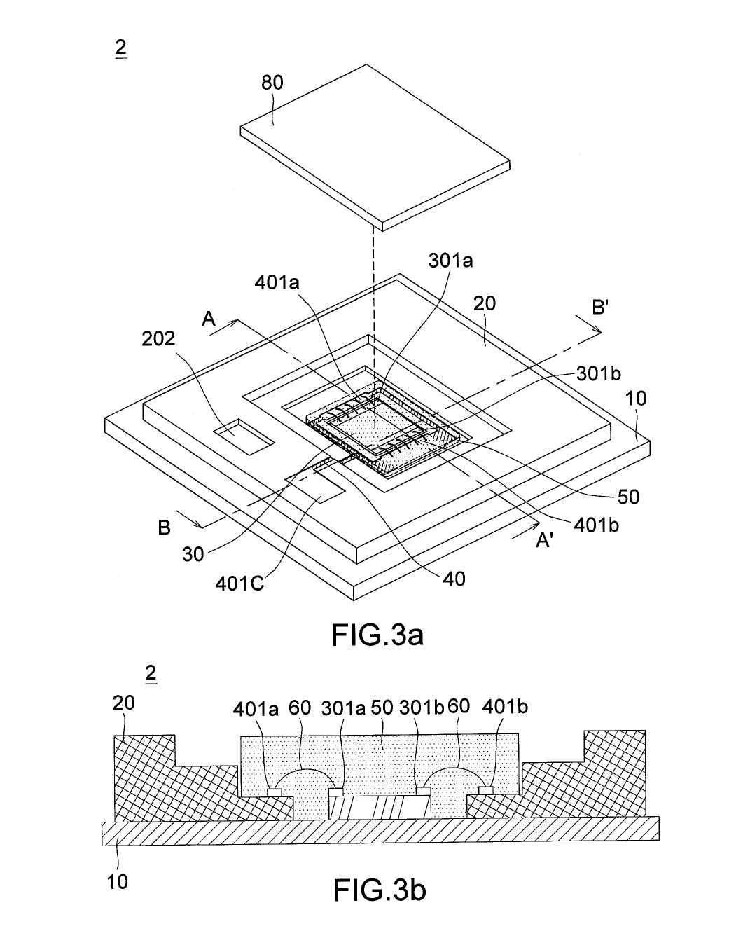

Referring to FIG. 3a, FIG. 3b and FIG. 3c, FIG. 3a is a schematic diagram illustrating the package structure of the concentrated photovoltaic cell 2 according to another embodiment; FIG. 3b is an A-A′ cross-sectional diagram illustrating the package structure of the concentrated photovoltaic cell 2 according the embodiment shown in FIG. 3a; FIG. 3c is a B-B′ cross-sectional diagram illustrating the package structure of the concentrated photovoltaic cell 2 according to the embodiment shown in FIG. 3a. The insulating material 20 is a 3D structure, and the insulating material 20 and the circuit wiring layer 40 form a 3D circuit board. It has to be explained that in the package structure of the concentrated photovoltaic cell 2, the photovoltaic chip 30 has top contacts 301a, 301b on the upper surface, and the circuit wiring layer 40 exposes the wiring contacts 401a, 401b, respectively connected to the top contacts 301a, 301b electrically through a plurality of wires 60. Preferably, a wiring contact 401c is exposed at an appropriate location of the circuit wiring layer 40 in accordance with the location of the second opening 202 of the insulating material 20. Therefore, the metal substrate 10 exposed from the second opening 202 of the insulating material 20 and the wiring contacts 401c respectively become external electrodes of the package structure of the concentrated photovoltaic cell 2 according to the present embodiment to connect electrically externally. The package resin highly pervious to light 50 encapsulates the photovoltaic chip 30 and a portion of the circuit wiring layer 40. The package structure of the concentrated photovoltaic cell 2 according to the present embodiment further includes a light-pervious plate 80 disposed on the insulating material 20, wherein the photovoltaic chip 30 is located with in the range of the light-pervious plate 80. For example, the insulating material 20 can be a staircase structure forming an accommodating space for the light-pervious plate 80 as shown in FIG. 3, but the insulating material 20 is not limited to be implemented as such staircase structure. The addition of the light-pervious plate 80 may block the pollutants such as the external dust and cotton fiber, ensuring the photovoltaic chip 30 to operate normally. The material of the light-pervious plate 80 includes acrylate, tempered glass, glass or polycarbonate.

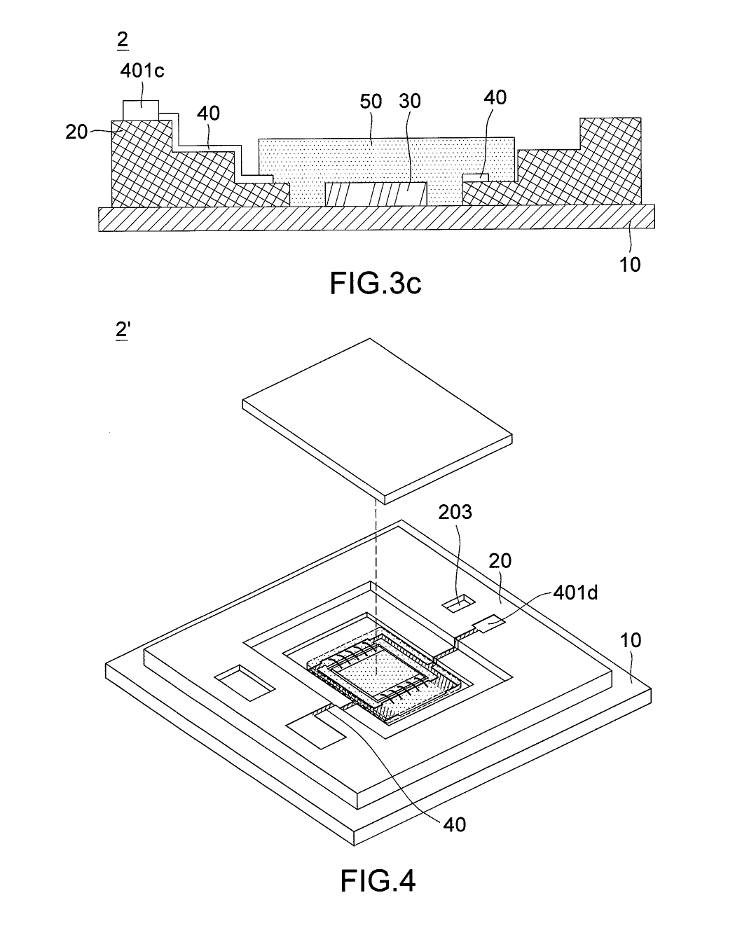

It is comprehensible that the number of openings exposing the metal substrate 10 and the number of exposed wiring contacts on the circuit wiring layer 40 can be modified according to the actual needs. Taking FIG. 4 as an example, FIG. 4 is a schematic diagram illustrating the package structure of the concentrated photovoltaic cell 2′ according to another embodiment. The insulating material 20 further includes a third opening 203; the wiring layer 40 further includes a wiring contact 401d. The metal substrate 10 exposed from the third opening 203 and the wiring contact 401d respectively become external electrodes for connecting electrically externally.

In summary, in the package structure of the concentrated photovoltaic cell according to the present invention, the bottom contact the photovoltaic chip is electrically connected to the metal substrate. The metal substrate not only becomes an electrode, but also conducts the heat generated by the photovoltaic chip away, providing the function of heat dissipation.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A package structure of a concentrated photovoltaic cell comprising:
a metal substrate;
an insulating material disposed on the metal substrate and having a first opening and a second opening exposing the metal substrate;
a photovoltaic chip having at least one top contact and a bottom contact respectively on the upper surface and the lower surface of the photovoltaic chip, wherein the photovoltaic chip is disposed in the first opening of the insulating material, and the bottom contact of the photovoltaic chip is electrically connected to the metal substrate;
a circuit wiring layer disposed on the insulating material, and exposing at least one wiring contact electrically connected to the top contact of the photovoltaic chip through at least one wire, wherein the metal substrate exposed from the second opening and the wiring contact of the circuit wiring layer respectively become external electrodes for connecting electrically externally; and
a package resin highly pervious to light encapsulating the photovoltaic chip and part of the circuit wiring layer.

2. The package structure of the concentrated photovoltaic cell according to claim 1, wherein the insulating material is a 3D structure, and the insulating material and the circuit wiring layer form a 3D circuit board.

3. The package structure of the concentrated photovoltaic cell according to claim 2, further comprising a light-pervious plate disposed on the 3D circuit board, wherein the photovoltaic chip is located within the range of the light-pervious plate.

4. The package structure of the concentrated photovoltaic cell according to claim 3, the material of the light-pervious plate comprises acrylate, tempered glass, glass or polycarbonate.

5. The package structure of the concentrated photovoltaic cell according to claim 1, further comprising a protecting element disposed on the circuit wiring layer, wherein the protecting element includes an opening, and the opening exposes the photovoltaic chip.

6. The package structure of the concentrated photovoltaic cell according to claim 5, further comprising a light-pervious plate disposed on the protecting element, wherein the photovoltaic chip is located within the range of the light-pervious plate.

7. The package structure of the concentrated photovoltaic cell according to claim 6, wherein the material of the light-pervious plate comprises acrylate, tempered glass, glass or polycarbonate.

8. The package structure of the concentrated photovoltaic cell according to claim 1, wherein the material of the metal substrate comprises copper or aluminum.

9. The package structure of the concentrated photovoltaic cell according to claim 1, wherein the circuit wiring layer comprises:
a conductive wiring layer; and
a protecting layer disposed on the conductive wiring layer and exposing the wiring contact.

10. The package structure of the concentrated photovoltaic cell according to claim 1, wherein the photovoltaic chip comprises a gallium arsenide (GaAs) photovoltaic chip, an indium phosphide (InP) photovoltaic chip, or an indium gallium phosphide (InGaP) photovoltaic chip.
